(19) United States
(12) Patent Application Publication
(10) Pub. No.: US 2011/0285408 A1
(43) Pub. Date: Nov. 24, 2011

(54) Occupant detection apparatus

(75) Inventors: Masayoshi Satake, Okazaki-city (JP); Noboru Maeda, Chiryu-city (JP); Hiroyuki Mori, Obu-city (JP); Kouji Ootaka, Toyohashi-city (JP)

(73) Assignees: NIPPON SOKEN, INC., Nishio-city (JP); DENSO CORPORATION, Kariya-city (JP)

(21) Appl. No.: 13/068,724

(22) Filed: May 18, 2011

(30) Foreign Application Priority Data
May 19, 2010 (JP) 2010-115624

(51) Int. Cl. G01R 27/26

(52) U.S. Cl. 324/679

(57) ABSTRACT

An occupant detection apparatus includes a capacitive sensor, a signal applying circuit, a signal detector, and a voltage applying circuit. The capacitive sensor has an electrode. The signal applying circuit applies a voltage amplitude signal to the electrode during a first time period, but does not apply the voltage amplitude signal to the electrode during a second time period. The voltage amplitude signal has a voltage with a varying amplitude. The signal detector detects a change in an electric current flowing through the capacitive sensor during the first time period. The voltage applying circuit applies a predetermined voltage to the electrode during the entire first time period and during at least part of the second time period.

### CROSS REFERENCE TO RELATED APPLICATION

This application is based on and claims priority to Japanese Patent Application No. 2010-115624 filed on May 19, 2010, the contents of which are incorporated herein by reference.

### FIELD OF THE INVENTION

The present invention relates to an occupant detection apparatus for detecting presence or absence of an occupant on a vehicle seat having a capacitive sensor, in particular, for reducing radio noise caused when a sinusoidal signal is transmitted to the capacitive sensor to detect the presence or absence of the occupant.

### BACKGROUND OF THE INVENTION

FIG. 1 illustrates a conventional occupant detection apparatus 1 as disclosed in, for example, JP-3353817. The occupant detection apparatus 1 includes a mat-shaped capacitive sensor 2 and an occupant detection electronic control unit (ECU) 3. The capacitive sensor 2 is incorporated in a vehicle seat (not shown) and has sensing electrodes 2a-2c. The occupant detection ECU 3 has a switching circuit 4, a signal detection circuit 5, a sinusoidal generator 6, and a controller 7. The switching circuit 4 has switches SW1-SW3. The switches SW1-SW3 are connected at one end to the sensing electrodes 2a-2c, respectively. The switches SW1-SW3 are connected at the other end to the signal detection circuit 5. The sinusoidal generator 6 is connected to the signal detection circuit 5. The controller 7 is connected between the switching circuit 4 and the signal detection circuit 5. The controller 7 controls the switching circuit 4 so that a sinusoidal signal generated by the sinusoidal generator 6 can be applied to any of the sensing electrodes 2a-2c. Specifically, the controller 7 controls the switching circuit 4 by turning ON and OFF the switches SW1-SW3.

In the occupant detection apparatus 1, the sinusoidal signal generated by the sinusoidal generator 6 is applied to the sensing electrodes 2a-2c that are connected to the switches SW1-SW3 that are turned ON by the controller 7. Thus, a weak electric field is generated between the capacitive sensor 2 and a vehicle chassis (not shown). The electric field changes according to a position of an object (e.g., occupant) on the seat. The signal detection circuit 5 detects a change in current or voltage caused by the change in the electric field so that the object can be detected.

In an on-board apparatus such as the occupant detection apparatus 1, it is difficult to generate a negative voltage due to power supply constraints. Therefore, as shown in FIGS. 2A-2C, when a signal, such as a sinusoidal signal, having amplitude is used, an offset Vof is generally added to prevent the signal from having a voltage of zero or less. FIG. 2A illustrates a case where a sinusoidal signal SV1 is applied to the sensing electrode 2a during a period of time from a time t1 to a time t4. In the case of FIG. 2A, the offset voltage Vof added to the sinusoidal signal SV1 is increased to 2.5 volts at the time t1 so that the sinusoidal signal SV1 can have a center voltage of 2.5 volts. Then, when the application of the sinusoidal signal SV1 to the sensing electrode 2a is stopped at the time t4, the offset voltage Vof is reduced to zero.

FIG. 2B illustrates a case where a sinusoidal signal SV2 is applied to the sensing electrode 2b during a period of time from the time t1 to a time t2 and during a period of time from a time t3 to the time t4. In the case of FIG. 2B, the offset voltage Vof added to the sinusoidal signal SV2 is increased to 2.5 volts at the time t1 so that the sinusoidal signal SV2 can have the center voltage of 2.5 volts. Then, when the application of the sinusoidal signal SV2 to the sensing electrode 2b is stopped at the time t2, the offset voltage Vof is reduced to zero. Then, when the application of the sinusoidal signal SV2 to the sensing electrode 2b is restarted at the time t3, the offset voltage Vof is increased to 2.5 volts so that the sinusoidal signal SV2 can have the center voltage of 2.5 volt. Then, when the application of the sinusoidal signal SV2 to the sensing electrode 2b is stopped at the time t4, the offset voltage Vof is reduced to zero. As shown in FIG. 2C, the application of a sinusoidal signal SV3 to the sensing electrode 2c is performed in the same manner as the application of the sinusoidal signal SV2 to the sensing electrode 2b.

When the offset voltage is added to or removed from the sinusoidal signal, the sinusoidal signal sharply rises or falls. As a result, as shown in FIG. 3, radio noise N1 occurs. Likewise, since the sinusoidal signal has a high frequency, the radio noise N1 occurs when the sinusoidal signal is generated. Such a radio noise N1 affects other electronic devices mounted on a vehicle.

### SUMMARY OF THE INVENTION

In view of the above, it is an object of the present invention to provide an occupant detection apparatus for reducing radio noise that occurs when application of a sinusoidal signal to a capacitive sensor is started or stopped.

According to an aspect of the present invention, an occupant detection apparatus includes a capacitive sensor, a signal applying circuit, a signal detector, and a voltage applying circuit. The capacitive sensor has an electrode. The signal applying circuit applies a voltage amplitude signal to the electrode during a first time period, but does not apply the voltage amplitude signal to the electrode during a second time period. The voltage amplitude signal has a voltage with a varying amplitude. The signal detector detects a change in an electric current flowing through the capacitive sensor during the first time period. The voltage applying circuit applies a predetermined voltage to the electrode during the entire first time period and during at least part of the second time period.

According to another aspect of the present invention, an occupant detection apparatus includes a capacitive sensor, a signal applying circuit, a signal detector. The capacitive sensor has an electrode. The signal applying circuit applies a voltage amplitude signal to the electrode during a first time period, but does not apply the voltage amplitude signal to the electrode during a second time period. The voltage amplitude signal has a voltage with a varying amplitude. The signal detector detects a change in an electric current flowing through the capacitive sensor during the first time period. The signal applying circuit further includes a frequency modulator for modulating a frequency of the voltage amplitude signal during the first time period.

### BRIEF DESCRIPTION OF THE DRAWINGS

The above and other objectives, features and advantages of the present invention will become more apparent from the following detailed description made with check to the accompanying drawings. In the drawings:

FIG. 1 is a block diagram of a prior-art occupant detection apparatus;

FIGS. 2A-2C are timing diagrams of sinusoidal signals applied to electrodes of the occupant detection apparatus of FIG. 1;

FIG. 3 is a diagram illustrating radio noise;

FIG. 4 is a block diagram of an occupant detection apparatus according to a first embodiment of the present invention;

FIGS. 5A-5C are timing diagrams of sinusoidal signals applied to electrodes of the occupant detection apparatus of FIG. 4;

FIG. 6 is a block diagram of an occupant detection apparatus according to a second embodiment of the present invention;

FIGS. 7A-7E are timing diagrams of sinusoidal signals applied to electrodes of the occupant detection apparatus of FIG. 6;

FIG. 8 is a diagram illustrating radio noise, and

FIG. 9 is a block diagram of an occupant detection apparatus according to a third embodiment of the present invention.

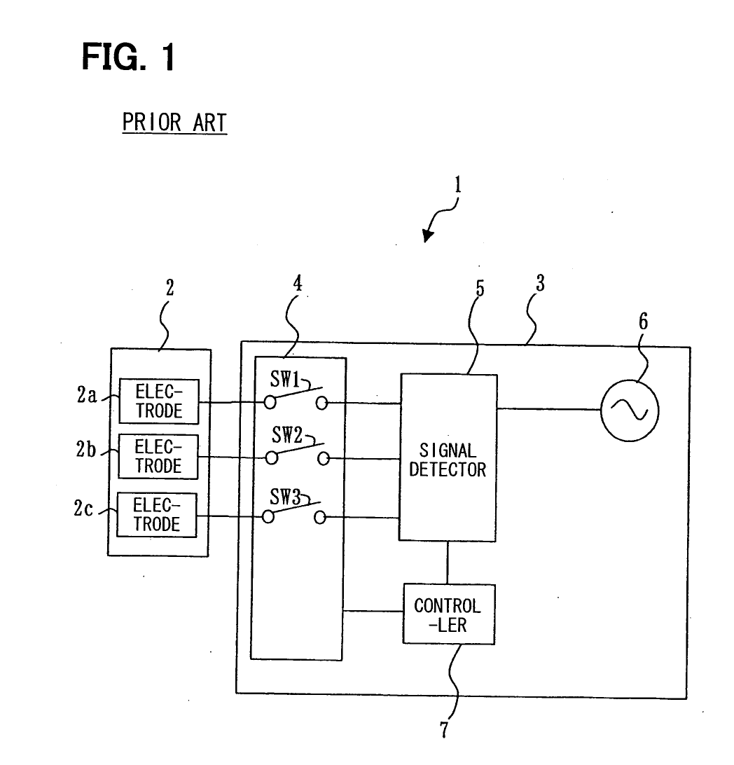

### DETAILED DESCRIPTION OF THE PREFERRED EMBODIMENTS

Embodiments of the present invention are described below with reference to the drawings. Throughout the embodiments, the same symbols are given to the same or corresponding parts in the drawings.

### First Embodiment

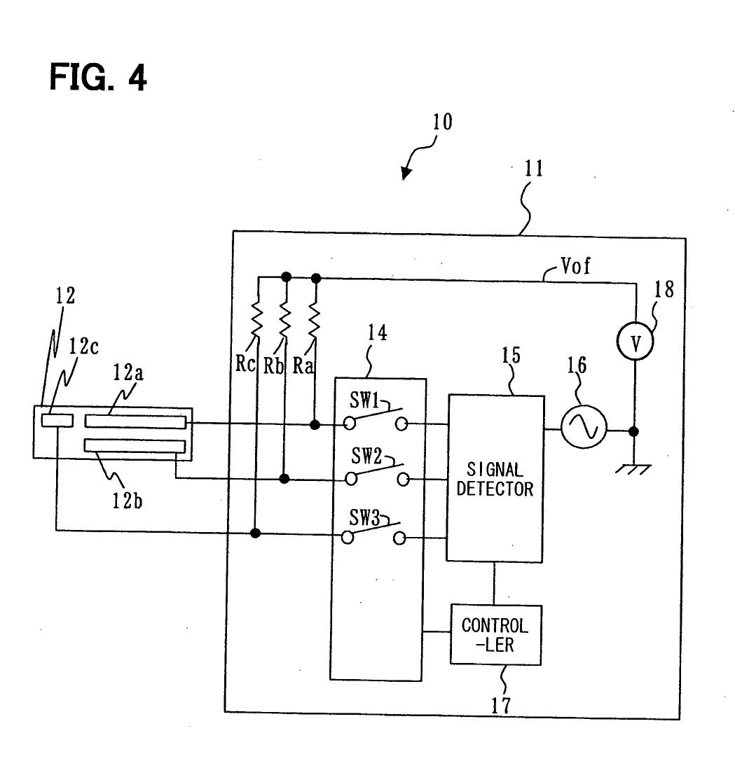

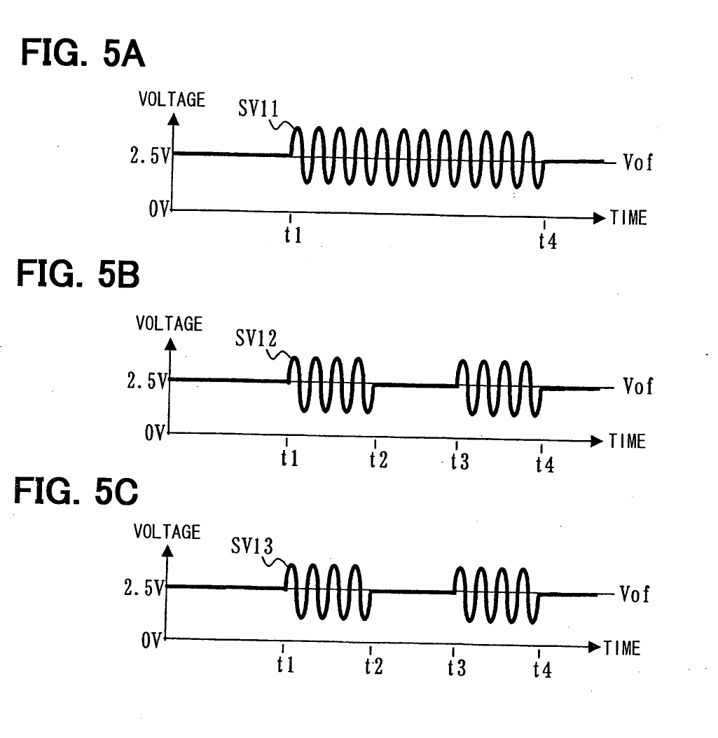

An occupant detection apparatus 10 according to a first embodiment of the present invention is described below with reference to FIGS. 4 and 5. The occupant detection apparatus 10 is mounted on a vehicle and included in an on-board system. The occupant detection apparatus 10 includes an occupant detection ECU 11 and a capacitive sensor 12 connected to the occupant detection ECU 11.

The capacitive sensor 12 has a primary electrode 12a, a guard electrode 12b, and a secondary electrode 12c. The primary electrode 12a and the secondary electrode 12c are located on a seat of a vehicle. The secondary electrode 12c is spaced from and in front of the primary electrode 12a in a vehicle front-rear direction. The guard electrode 12b is located between the primary electrode 12a and a vehicle chassis that serves as ground. The guard electrode 12b is spaced from the primary electrode 12a and the vehicle chassis.

The occupant detection ECU 11 has a switching circuit 14, a signal detection circuit 15, a sinusoidal generator 16, a controller 17, pull-up resistors Ra, Rb, Rc, and an offset voltage source 18. The switching circuit 14 has switches SW1-SW3. The switches SW1-SW3 are connected at one end to the electrodes 12a-12c, respectively. The switches SW1-SW3 are connected at the other end to the signal detection circuit 15. The sinusoidal generator 16 is connected to the signal detection circuit 15. The controller 17 is connected between the switching circuit 14 and the signal detection circuit 15. The controller 17 controls the switching circuit 14 so that a sinusoidal signal SV generated by the sinusoidal generator 16 can be applied to any of the electrodes 12a-12c. The pull-up resistors Ra, Rb, Rc are connected at one end to the electrodes 12a-12c. The pull-up resistor Ra is connected at the other end between the primary electrode 12a and the switch SW1. The pull-up resistor Rb is connected at the other end between the guard electrode 12b and the switch SW2. The pull-up resistor Rc is connected at the other end between the secondary electrode 12c and the switch SW3. The offset voltage source 18 applies an offset voltage Vof to the electrodes 12a-12c through the pull-up resistors Ra-Rc, respectively.

The offset voltage Vof prevents the electrodes 12a-12 from having a negative voltage, when the sinusoidal signal SV is applied to the electrodes 12a-12c. The controller 17 controls the switching circuit 14 by turning ON and OFF the switches SW1-SW3. The switching circuit 14 and the controller 17 form a switching device. The switching device and the sinusoidal generator 16 form a signal applying circuit. The pull-up resistors Ra-Rc and the offset voltage source 18 form a voltage applying circuit.

In the occupant detection apparatus 10, as shown in FIGS. 5A-5C, the offset voltage Vof is continuously applied to the electrodes 12a-12c by the offset voltage source 18. FIG. 5A illustrates a case where the sinusoidal signal SV is applied by the occupant detection ECU 11 to the primary electrode 12a during a period of time from a time t1 to a time t4. In the case of FIG. 5A, the switch SW1 of the switching circuit 14 is turned ON by the controller 17 at the time t1 so that the offset voltage Vof and the sinusoidal signal SV can be combined to form a sinusoidal signal SV11 having a center voltage of Vof. The sinusoidal signal SV11 is applied to the primary electrode 12a so that a voltage of the primary electrode 12a can vary with reference to the offset voltage Vof.

FIG. 5B illustrates a case where the sinusoidal signal SV is applied by the occupant detection ECU 11 to the guard electrode 12b during a period of time from the time t1 to a time t2 and during a period of time from a time t3 to the time t4. In the case of FIG. 5B, the switch SW2 of the switching circuit 14 is turned ON by the controller 17 at the time t1 so that the offset voltage Vof and the sinusoidal signal SV can be combined to form a sinusoidal signal SV12 having a center voltage of Vof. The sinusoidal signal SV12 is applied to the guard electrode 12b so that the voltage of the guard electrode 12b can vary with reference to the offset voltage Vof. Then, the switch SW2 is turned OFF by the controller 17 at the time t2 so that the application of the sinusoidal signal SV to the guard electrode 12b can be stopped. Then, the switch SW2 is turned ON by the controller 17 at the time t3 so that the offset voltage Vof and the sinusoidal signal SV can be combined to form the sinusoidal signal SV12. The sinusoidal signal SV12 is applied to the guard electrode 12b so that the voltage of the guard electrode 12b can vary with reference to the offset voltage Vof. Then, the switch SW2 is turned OFF by the controller 17 at the time t4 so that the application of the sinusoidal signal SV to the guard electrode 12b can be stopped. As shown in FIG. 5C, the application of a sinusoidal signal SV13 to the secondary electrode 12c is performed in the same manner as the application of the sinusoidal signal SV12 to the guard electrode 12b.

In the occupant detection apparatus 10, the application of the sinusoidal signals SV11-SV13 to the electrodes 12a-12c is controlled by turning ON and OFF the switches SW1-SW3 of the switching circuit 14 so that a weak electric field can be generated between the capacitive sensor 12 and the vehicle chassis (not shown). The electric field changes according to a position of an object (e.g., occupant) on the seat. The signal detection circuit 15 detects a change in current or voltage caused by the change in the electric field so that the object can be detected. For example, a central processing unit (CPU) determines whether the detected object is a child restraint system (CRS), a child, an adult, water, or nothing, and then an absorber ECU (e.g., airbag ECU) inflates or deflates an absorber (e.g., airbag) based on a result of the determination.

As described above, according to the first embodiment, the occupant detection apparatus 10 includes the capacitive sensor 12 having at least one electrode, the signal applying circuit configured to apply the sinusoidal signal SV, as a voltage amplification signal, to the electrode during a first time period and configured not to apply the sinusoidal signal SV to the electrode during a second time period, and the signal detection circuit 15 configured to detect a change in an electric current flowing through the capacitive sensor 12 during the first time period.

In addition, according to the first embodiment, the occupant detection apparatus 10 includes the voltage applying circuit configured to apply the offset voltage Vof as a predetermined voltage (e.g., constant voltage) to the electrode during the entire first time period and during at least part of the second time period. In an example shown in FIG. 5B, the first time period corresponds to the time period from the time t1 to the time t2 and the time period from the time t3 to time t4 in FIG. 5B, and the second time period corresponds to the time period from the time t2 to the time t3.

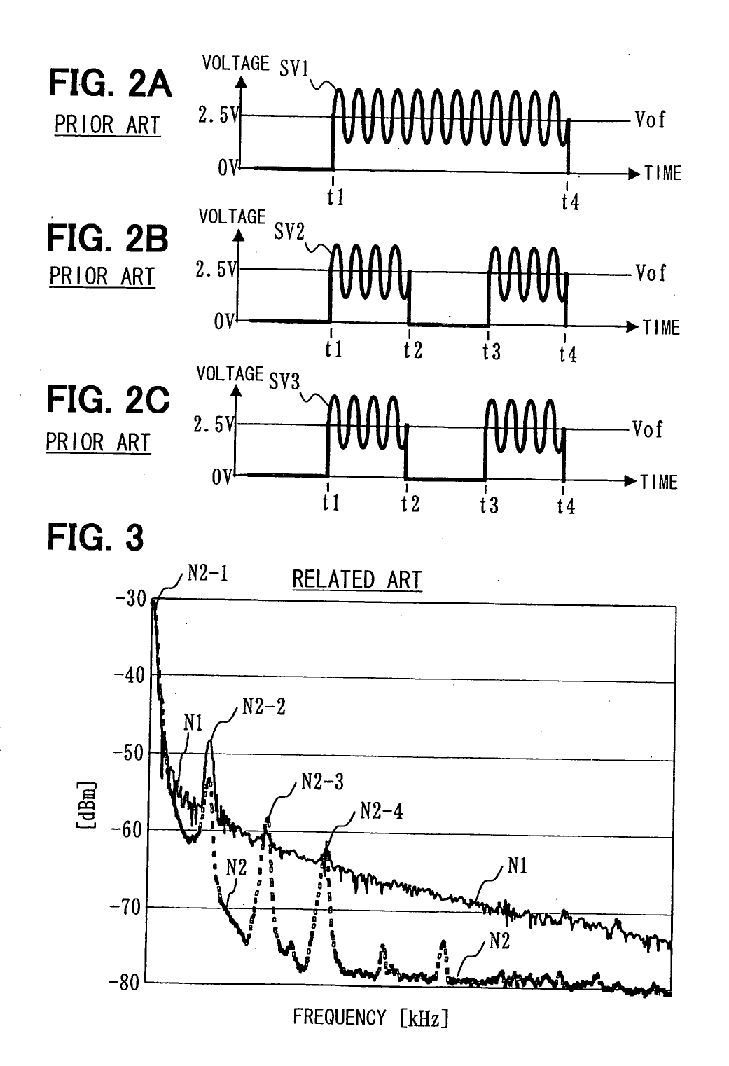

In the prior-art shown in FIGS. 2A-2C, the offset voltage is applied only during the first time period where the sinusoidal signal SV is applied to the electrode. In contrast, according to the first embodiment, the offset voltage is applied not only during the first time period but also at least part of the second time period where the sinusoidal signal SV is not applied to the electrode. For example, the part of the second time period can immediately precede or follow the first time period. In such an approach, it is possible to prevent the voltage of the electrode from varying sharply when application of the sinusoidal signal SV to the electrode is started or stopped. Thus, radio noise can be reduced.

In FIG. 3, N1 represents radio noise occurring in the prior-art, and N2 represents radio noise occurring in the occupant detection apparatus 10 according to the first embodiment. The radio noise N2 has the first harmonic wave N2-1 as a fundamental harmonic, the second harmonic wave N2-2, the third harmonic wave N2-3, and the fourth harmonic wave N2-4, . . . , and the Nth harmonic wave. As can be seen from FIG. 3, the radio noise N2 is smaller than the radio noise N1 over almost the entire frequency range.

In the first embodiment, the voltage amplification signal applied to the electrode of the capacitive sensor 12 is sinusoidal. Alternatively, the voltage amplification signal can be triangular or square according to characteristics of the capacitive sensor 12.

The part of the second time period can immediately precede and/or follow the first time period.

In such an approach, it is possible to prevent the voltage of the electrode from varying sharply when application of the sinusoidal signal SV to the electrode is started or stopped. Thus, radio noise can be reduced.

For example, the voltage applying circuit applies the offset voltage to the electrode during the entire second time period. In such an approach, the second time period immediately precedes and follows the first time period so that radio noise can be surely reduced.

The sinusoidal signal SV and the offset voltage Vof are combined so that the voltage of the electrode varies in amplitude with reference to the offset voltage Vof.

The offset voltage Vof has a value that allows the combined signal of the sinusoidal signal SV and the offset voltage Vof to have a voltage of zero or more. Thus, it is possible to prevent a negative voltage is applied to the electrode of the capacitive sensor 12.

The signal applying circuit includes the sinusoidal generator 16 for generating the sinusoidal signal SV and the switching circuit 14 for selectively applying the sinusoidal signal SV to the electrodes 12a-12c. Thus, the sinusoidal signal SV can be applied to any of the electrodes 12a-12c.

The voltage applying circuit includes the pull-up resistors Ra-Rc and the offset voltage source 18. The pull-up resistors Ra-Rc are connected at one end between the electrodes 12a-12c and the switching circuit 14. The offset voltage source 18 applies the offset voltage V0 to the electrodes 12a-12c through the pull-up resistors Ra-Rc. In such an approach, the offset voltage Vof can be continuously applied to the electrodes 12a-12c.

Alternatively, a constant voltage source (not shown) can be used to continuously apply the offset voltage Vof to the electrodes 12a-12c instead of the pull-up resistors Ra-Rc and the offset voltage source 18.

### Second Embodiment

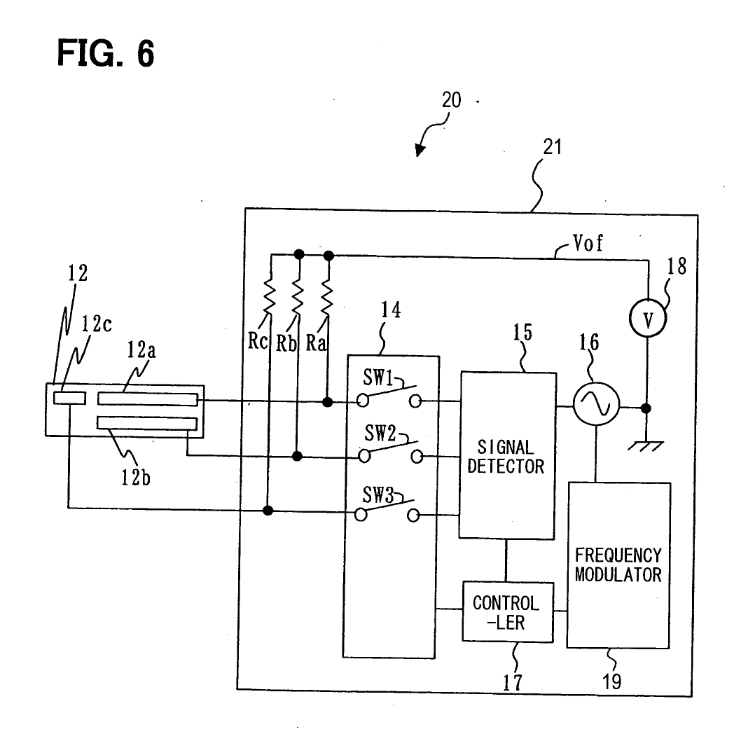

An occupant detection apparatus 20 according to a second embodiment of the present invention is described below with reference to FIGS. 6-8. A difference of the occupant detection apparatus 20 from the occupant detection apparatus 10 is that a frequency modulator 19 is added between the sinusoidal generator 16 and the controller 17 of an occupant detection ECU 31. The frequency modulator 19 modulates a frequency of the sinusoidal signal SV generated by the sinusoidal generator 16 so that the sinusoidal signal SV can have a predetermined frequency. For example, assuming that the sinusoidal signal SV has a first frequency f1 during a first time period where the occupant detection is performed and has a second frequency f2 during a second time period where the occupant detection is not performed, the frequency modulator 19 modulates the sinusoidal signal SV from the first frequency f1 to the second frequency f2 at the transition from the first time period to the second time period.

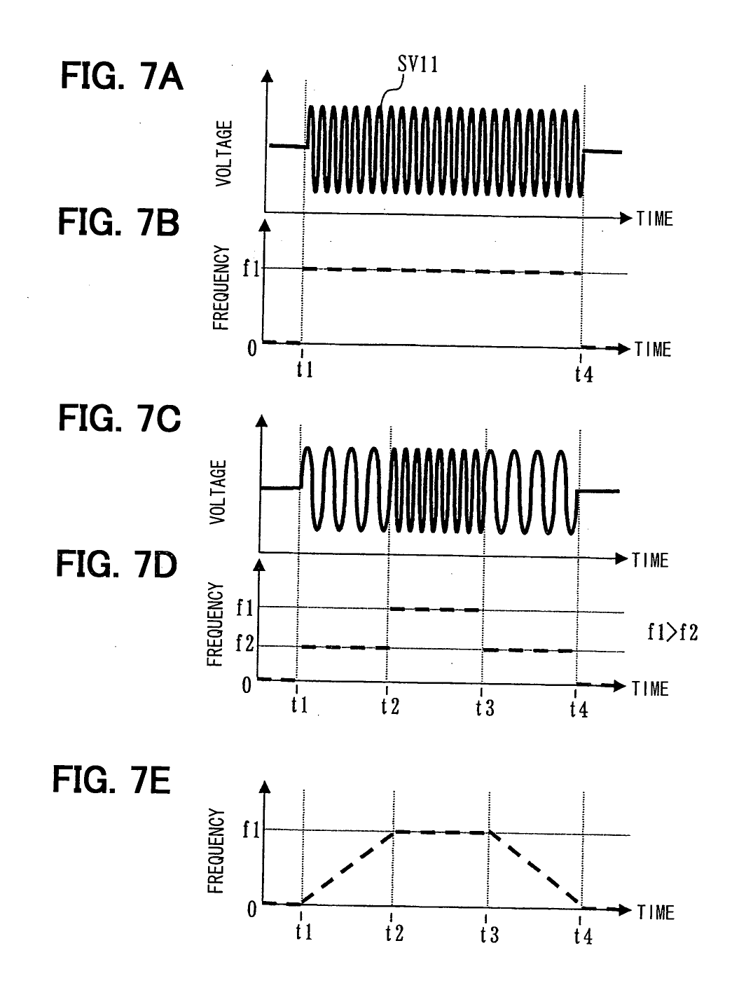

The frequency modulation performed by the frequency modulator 19 is described in detail below. FIGS. 7A and 7B illustrate a case where the occupant detection is performed during a period of time from a time t1 to a time t4. In the case of FIGS. 7A and 7B, the switch SW1 of the switching circuit 14 is turned ON by the controller 17 at the time t1 so that the sinusoidal signal SV11 can be applied to the primary electrode 12a. Since the occupant detection is performed during the entire period of time from the time t1 to the time t4, the sinusoidal signal SV11 is maintained at the first frequency f1 as shown in FIG. 7B. That is, the frequency modulator 19 does not perform the frequency modulation.

FIGS. 7C and 7D illustrate a case where the occupant detection is performed only during a period of time from a time t2 to a time t3. In other words, FIGS. 7C and 7D illustrate a case where the occupant detection is not performed during a period of time from the time t1 to the time t2 and during a period of time from the time t3 to the time t4. In the case of FIGS. 7C and 7D, the switch SW1 of the switching circuit 14 is turned ON by the controller 17 at the time t1 so that the sinusoidal signal SV11 can be applied to the primary electrode 12a. At the same time, the frequency modulator 19 performs the frequency modulation so that the sinusoidal signal SV11 can have the second frequency f2, as shown in FIG. 7D. Thus, after the time t1, the sinusoidal signal SV11 having the second frequency f2 is applied to the primary electrode 12a through the switch SW1.

Then, at the time t2, the frequency modulator 19 performs the frequency modulation so that the sinusoidal signal SV11 can change from the second frequency f2 to the first frequency f1 greater than the second frequency f2, as shown in FIG. 7D. Thus, after the time t2, the sinusoidal signal SV11 having the first frequency f1 is applied to the primary electrode 12a through the switch SW1 so that the occupant detection can be performed by the signal detection circuit 15.

Then, at the time t3, the frequency modulator 19 performs the frequency modulation so that the sinusoidal signal SV11 can change from the first frequency f1 back to the second frequency f2, as shown in FIG. 7D. Thus, after the time t3, the sinusoidal signal SV11 having the second frequency f2 is applied to the primary electrode 12a through the switch SW1 so that the occupant detection can be stopped. Then, at the time t4, the switch SW1 of the switching circuit 14 is turned OFF by the controller 17 so that the application of the sinusoidal signal SV11 to the primary electrode 12a can be stopped.

As described above, according to the second embodiment, the occupant detection apparatus 20 further includes the frequency modulator 19 for modulating the frequency of the sinusoidal signal SV generated by the sinusoidal generator 16. That is, the signal applying circuit further includes the frequency modulator 19 in addition to the switching circuit 14, the sinusoidal generator 16, and the controller 17.

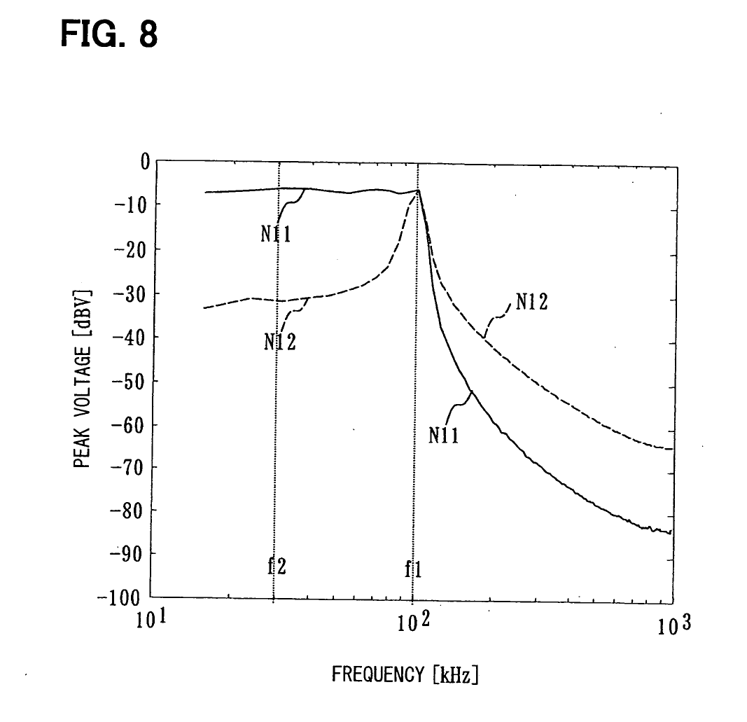

Thus, immediately before or after the sinusoidal signal having the first frequency f1 is applied to the electrode of the capacitive sensor 12 to perform the occupant detection, the frequency of the sinusoidal signal can be modulated by the frequency modulator 19 to the second frequency f2 lower than the first frequency f1. When the sinusoidal signal has the second frequency f2, the change in amplitude of the voltage of the electrode is small. Thus, as shown in FIG. 8, radio noise can be reduced. In FIG. 8, N11 represents radio noise occurring in the occupant detection apparatus 20 according to the second embodiment, and N12 represents radio noise occurring in the prior-art.

Further, when the occupant detection is started, the frequency of the sinusoidal signal applied to the electrode gradually changes from zero through the second frequency f2 to the first frequency f1. Therefore, as compared to when the frequency of the sinusoidal signal changes from zero directly to the first frequency f1, the radio noise can be reduced.

Further, when the occupant detection is stopped, the frequency of the sinusoidal signal applied to the electrode gradually changes from the first frequency f1 through the second frequency f2 to zero. Therefore, as compared to when the frequency of the sinusoidal signal changes from the first frequency f1 directly to zero, the radio noise can be reduced.

The frequency modulator 19 is connected between the signal applying circuit and the switching circuit 14. In such an approach, the frequency of the sinusoidal signal applied to the electrode through the switching circuit 14 can be modulated by the frequency modulator 19.

In the second embodiment, the frequency of the sinusoidal signal changes stepwise in two steps between zero and the first frequency f1. Alternatively, the frequency of the sinusoidal signal can change stepwise in three or more steps. In such an approach, the radio noise can be more reduced.

Alternatively, as shown in FIG. 7E, the frequency of the sinusoidal signal can change continuously between zero and the first frequency f1. In such an approach, the radio noise can be more reduced.

### Third Embodiment

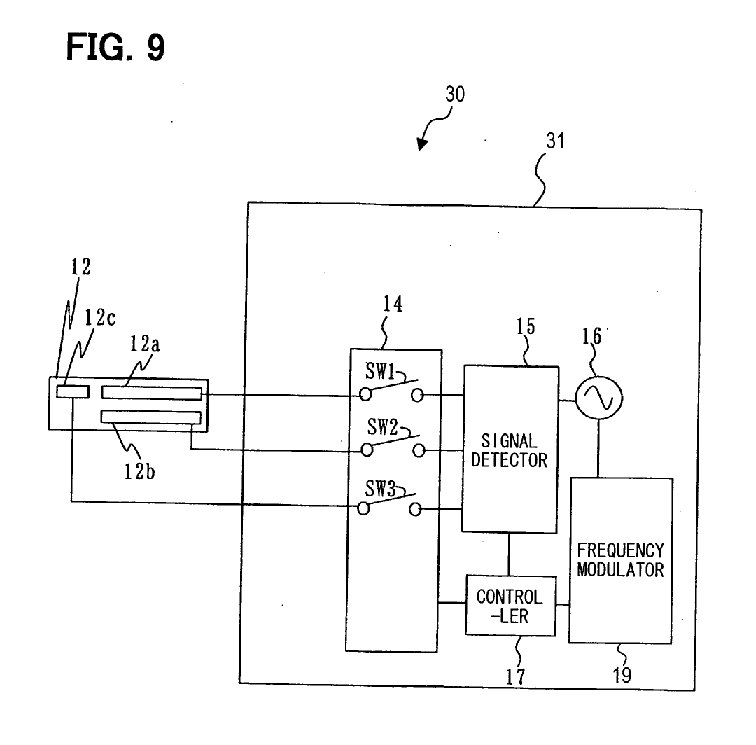

An occupant detection apparatus 30 according to a second embodiment of the present invention is described below with reference to FIG. 9. A difference of the occupant detection apparatus 30 from the occupant detection apparatus 20 is that the pull-up resistors Ra, Rb, Rc and the offset voltage source 18 are removed from an occupant detection ECU 31. That is, in the occupant detection apparatus 30, the offset voltage Vof is not continuously applied to the electrodes 12a-12c.

Like the occupant detection apparatus 20 of the second embodiment, the occupant detection apparatus 30 has the frequency modulator 19. Therefore, immediately before or after the sinusoidal signal having the first frequency f1 is applied to the electrode of the capacitive sensor 12 to perform the occupant detection, the frequency of the sinusoidal signal can be modulated by the frequency modulator 19 to the second frequency f2 lower than the first frequency f1.

In such an approach, the occupant detection apparatus 30 can have the same advantages as the occupant detection apparatus 20. Thus, the radio noise can be reduced.

### MODIFICATIONS

The embodiments described above can be modified in various ways. For example, the occupant detection apparatus 10, 20, 30 can have an occupant detection mode for detecting presence or absence of an occupant on a vehicle seat and a water detection mode for detecting presence or absence of water on the vehicle seat. In other words, in the wet detection mode, it is detected whether the vehicle seat is wet. For example, the occupant detection mode can use the primary electrode 12a and the guard electrode 12b, and the water detection mode can use the primary electrode 12a and the secondary electrode 12c. In this case, the offset voltage Vof as a predetermined voltage can be continuously applied to the secondary electrode 12c in the occupant detection mode, and the offset voltage Vof can be continuously applied to the guard electrode 12b in the water detection mode.

Such changes and modifications are to be understood as being within the scope of the present invention as defined by the appended claims.

What is claimed is:

1. An occupant detection apparatus comprising:
a capacitive sensor having an electrode;
a signal applying circuit configured to apply a voltage amplitude signal to the electrode during a first time period and configured not to apply the voltage amplitude signal to the electrode during a second time period, the voltage amplitude signal having a voltage with a varying amplitude;
a signal detector configured to detect a change in an electric current flowing through the capacitive sensor during the first time period; and
a voltage applying circuit configured to apply a predetermined voltage to the electrode during the entire first time period and during at least part of the second time period.

2. The occupant detection apparatus according to claim 1, wherein
the voltage amplitude signal is a sinusoidal wave signal, a triangular wave signal, or a square wave signal.

3. The occupant detection apparatus according to claim 1, wherein
the at least part of the second time period immediately precedes or follows the first time period.

4. The occupant detection apparatus according to claim 1, wherein
the voltage applying circuit applies the predetermined voltage to the electrode during the entire second time period.

5. The occupant detection apparatus according to claim 1, wherein
the voltage amplitude signal and the predetermined voltage are combined so that a voltage of the electrode varies in amplitude with reference to the predetermined voltage.

6. The occupant detection apparatus according to claim 1, wherein
the voltage amplitude signal and the predetermined voltage are combined so that a voltage of the electrode exceeds zero.

7. The occupant detection apparatus according to claim 1, wherein
the signal applying circuit includes a signal generator for generating the voltage amplitude signal and a switching device for selectively applying the voltage amplitude signal to the electrode.

8. The occupant detection apparatus according to claim 7, wherein
the voltage applying circuit includes a pull-up resistor and a voltage source,
the pull-up resistor is connected between the electrode and the switching device, and
the voltage source applies the predetermined voltage to the electrode through the pull-up resistor.

9. The occupant detection apparatus according to claim 1, wherein
the voltage applying circuit includes a voltage source, and
the voltage source applies the predetermined voltage to the electrode during the at least part of the second time period.

10. The occupant detection apparatus according to claim 7 wherein
the signal applying circuit includes a frequency modulator for modulating a frequency of the voltage amplitude signal.

11. The occupant detection apparatus according to claim 10 wherein
the frequency modulator increases the frequency of the voltage amplitude signal during a first part of the first time period.

12. The occupant detection apparatus according to claim 11 wherein
the frequency modulator reduces the frequency of the voltage amplitude signal during a second part of the first time period, and
the second part of the first time period immediately follows the first part of the first time period.

13. The occupant detection apparatus according to claim 10 wherein
the frequency modulator is connected between the signal applying circuit and the switching device.

14. The occupant detection apparatus according to claim 10 wherein
the frequency modulator modulates the frequency of the voltage amplitude signal so that the frequency of the voltage amplitude signal changes stepwise.

15. The occupant detection apparatus according to claim 10 wherein
the frequency modulator modulates the frequency of the voltage amplitude signal so that the frequency of the voltage amplitude signal changes continuously.

16. The occupant detection apparatus according to claim 1, wherein
the electrode of the capacitive sensor comprises a primary electrode, a guard electrode, and a secondary electrode,
the primary electrode is adapted to be located on a vehicle seat,
the guard electrode is spaced from the primary electrode and located between the primary electrode and a seat frame connected to vehicle ground,
the secondary electrode is located adjacent to the primary electrode,
the occupant detection apparatus has an occupant detection mode for detecting presence or absence of an occupant on the vehicle seat and a water detection mode for detecting presence or absence of water on the vehicle seat,
the occupant detection mode uses the primary electrode and the guard electrode,
the water detection mode uses the primary electrode and the secondary electrode,
in the occupant detection mode, the voltage applying circuit applies the predetermined voltage to the secondary electrode, and
in the water detection mode, the voltage applying circuit applies the predetermined voltage to the guard electrode.

17. An occupant detection apparatus comprising:
a capacitive sensor having an electrode;
a signal applying circuit configured to apply a voltage amplitude signal to the electrode during a first time period and configured not to apply the voltage amplitude signal to the electrode during a second time period, the voltage amplitude signal having a voltage with a varying amplitude; and
a signal detector configured to detect a change in an electric current flowing through the capacitive sensor during the first time period, wherein
the signal applying circuit further includes a frequency modulator for modulating a frequency of the voltage amplitude signal during the first time period.
